(19) United States
(12) Patent Application Publication
(10) Pub. No.: US 2007/0123019 A1
(43) Pub. Date: May 31, 2007

(54) METHODS OF FORMING CARBON NANOTUBES IN A WIRING PATTERN AND RELATED DEVICES

(75) Inventors: Seung-Hyun Lim, Seoul (KR); Sun-Woo Lee, Incheon (KR); In-Seok Yeo, Seoul (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 11/470,369

(22) Filed: Sep. 6, 2006

(30) Foreign Application Priority Data
Sep. 6, 2005 (KR) 10-2005-0082595

(51) Int. Cl. H01L 21/44

(52) U.S. Cl. 438/611

(57) ABSTRACT

A method of forming a carbon nanotube includes forming a cavity between a substrate and a first layer on the substrate. The cavity extends in a wiring pattern and includes a metal catalyst pattern in the cavity. The carbon nanotube is formed from the metal catalyst pattern and extends inside the cavity along the wiring pattern. Related methods and devices are also discussed.

### CROSS-REFERENCE TO RELATED APPLICATION

This application claims priority under 35 USC § 119 from Korean Patent Application No. 10-2005-82595 filed on Sep. 6, 2005, the disclosure of which is hereby incorporated by reference herein in its entirety.

### FIELD OF THE INVENTION

The present invention relates to integrated circuit devices, and more particularly, to methods of forming carbon nanotubes for use in integrated circuit devices.

### BACKGROUND OF THE INVENTION

As the demand for information increases, research to develop more efficient information processing devices has been pursued. For example, integrated circuit devices have been developed to provide greater capacity and faster response speed. As a result, memory cells in the integrated circuit devices have become highly integrated on semiconductor substrates.

Accordingly, the conductive wiring in the integrated circuit devices may have reduced dimensions as the integrated circuit devices are scaled-down into the nanometer range. When the dimensions of the conductive wiring in an integrated circuit device are so reduced, some problems may occur, which may deteriorate the electrical characteristics of the integrated circuit device. For example, the resistance of the conductive wiring may be greatly increased due to the reduced dimensions. Also a “hillock” phenomenon (i.e., an electrical short that may be caused by electro-migration) may be generated in the integrated circuit device. In other words, under the influence of current, metal atoms may be deposited in a wire to form a surface protrusion and thus a void, which may cause problems due to the reduced line widths. Further, a diffusion barrier layer may not be precisely formed on such small conductive wiring.

In light of such problems, carbon nanotubes (CNT) have been developed for use as conductive wiring in integrated circuit devices. The carbon nanotubes may have a one-dimensional quantum wiring structure and may have relatively good electrical characteristics, such as one-dimensional quantum transportation, etc. More particularly, the carbon nanotubes may provide improved current density, which may be significantly larger than that of conventional metal wiring. For example, conventional copper wiring may have a current density of about 106 A/cm², while carbon nanotubes may have a current density of about 110 A/cm² to about 1,010 cm².

In addition, carbon nanotubes may offer good mechanical strength and chemical stability, so that electrical shorts that may be generated by electro-migration effects may be reduced and/or avoided when carbon nanotubes are used as conductive wirings in integrated circuit devices. Additionally, the wiring including carbon nanotubes may not require a diffusion barrier layer, because the carbon atoms in the carbon nanotubes may not be diffused into a silicon substrate and/or other metal wirings.

Conventional carbon nanotubes may typically be formed by a chemical vapor deposition (CVD) process. The carbon nanotubes may be adjusted so as to be used as a conductive wiring in an integrated circuit device. In other words, the carbon nanotubes may be manipulated to provide a desired shape when used as conductive wiring in an integrated circuit device. For example, a plurality of carbon nanotubes may be arranged on a substrate and adjusted to obtain a desired structure after the carbon nanotubes are formed on the substrate in a random structure. However, it may be difficult to arrange the carbon nanotubes to thereby obtain the desired wiring pattern on the substrate. Further, several additional processes may be required to obtain the desired wiring pattern, and an amount of a source gas that may be required to form the carbon nanotubes may be increased.

### SUMMARY OF THE INVENTION

Some embodiments of the present invention may provide methods of forming a wiring including a carbon nanotube to have a desired structure.

Some embodiments of the present invention may also provide methods of forming a wiring including a carbon nanotube by reducing an amount of a source gas for forming the wiring.

According to some embodiments of the present invention, a method of forming a wiring including a carbon nanotube may be provided. In the method of forming the wiring including the carbon nanotube, a sacrificial layer pattern may be formed on a substrate. After an insulation layer is formed on the substrate to cover the sacrificial layer pattern, a contact hole exposing a portion of the substrate may be formed by partially etching the insulation layer and the sacrificial layer pattern. A spacer may be formed on sidewalls of the contact hole, and a metal catalyst pattern may be formed in the contact hole. The metal catalyst pattern may be partially buried in the exposed portion of the substrate. A cavity and/or a tunnel may be formed between the substrate and the insulation layer by removing the spacer and the sacrificial layer pattern. The wiring including the carbon nanotube may be formed in the cavity and the contact hole.

In some embodiments of the present invention, the insulation layer may be formed using a material having an etching selectivity relative to the sacrificial layer pattern. Additionally, the spacer may be formed using a material substantially the same as that of the sacrificial layer pattern. For example, the sacrificial layer pattern and the spacer may be formed using silicon compound, such as silicon-germanium.

In the formation of the sacrificial layer pattern according to some embodiments of the present invention, a sacrificial layer may be formed on the substrate. The sacrificial layer may be partially etched to form the sacrificial layer pattern that includes a first portion extending along a first direction and a second portion extending along a second direction substantially perpendicular to the first direction. The contact hole may be positioned on a portion of the sacrificial layer pattern where the first portion is connected to the second portion.

In other embodiments of the present invention, a recess may be formed on the exposed portion of the substrate prior to forming the catalytic metal layer pattern. The catalytic metal layer pattern may be formed by forming a metal layer on the insulation layer to fill the recess and the contact hole, and partially removing the metal layer until the insulation layer is exposed to form the catalytic metal layer pattern. The catalytic metal layer pattern may have an upper surface substantially lower than that of the insulation layer. The metal layer may be partially removed by a chemical mechanical polishing process and/or a first etching process and a second etching process.

In some embodiments of the present invention, the spacer and the sacrificial layer pattern may be simultaneously removed using an etching solution. The etching solution may include a carboxylic acid (CH₃COOH) solution, a hydrogen fluoride (HF) solution and/or a hydrogen peroxide (H₂O₂) solution.

In the formation of the wiring including the carbon nanotube according to some embodiments of the present invention, a source material may be provided onto the catalytic metal layer pattern through the contact hole. The wiring may be formed in the cavity and the contact hole by growing the carbon nanotube from the catalytic metal layer pattern. The wiring may enclose the catalytic metal layer pattern.

According to other embodiments of the present invention, in a method of forming a wiring including the carbon nanotube, a sacrificial layer pattern may be formed on a substrate. After a first insulation layer is formed on the substrate to cover the sacrificial layer pattern, a contact hole exposing a first portion of the substrate may be formed by partially removing the first insulation layer and the sacrificial layer pattern. A spacer may be formed on sidewalls of the contact hole, and a catalytic metal layer pattern may be formed to partially fill up the contact hole. The catalytic metal layer pattern may be partially buried in the exposed first portion of the substrate. A second insulation layer pattern may be formed on the catalytic metal layer pattern to fill the contact hole. An opening exposing a second portion of the substrate may be formed by partially removing the first insulation layer and the sacrificial layer pattern. A cavity may be formed between the substrate and the first insulation layer by removing the spacer and the sacrificial layer pattern, and the wiring including the carbon nanotube may be formed in the cavity, the opening and the contact hole.

In the formation of the sacrificial layer pattern according to some embodiments of the present invention, a sacrificial layer may be formed on the substrate, and the sacrificial layer may be partially etched to form the sacrificial layer pattern that includes a first portion extending along a first direction and a second portion extending along a second direction substantially perpendicular to the first direction. The contact hole may expose a portion of the sacrificial layer pattern where the first portion is connected to the second portion, and the opening may expose the first portion of the sacrificial layer pattern.

In some embodiments of the present invention, a lower portion of the catalytic metal layer pattern may be buried in a recess formed on the exposed first portion of the substrate.

In other embodiments of the present invention, the catalytic metal layer pattern may be formed by forming a metal layer on the insulation layer to fill the recess and the contact hole, and partially removing the metal layer until the first insulation layer is exposed to form the catalytic metal layer pattern. The catalytic metal layer pattern may have an upper surface substantially lower than that of the first insulation layer.

In the formation of the wiring including the carbon nanotube according to some embodiments of the present invention, a source gas including carbon may be provided onto the catalytic metal layer pattern through the opening. The wiring may be formed in the cavity, the contact hole and the opening by growing the carbon nanotube from the catalytic metal layer pattern.

In other embodiments of the present invention, a third insulation layer may be formed on the first insulation layer and the second insulation layer pattern to cover the wiring including the carbon nanotube.

According to further embodiments of the present invention, a method of forming a carbon nanotube may include forming a cavity between a substrate and a first layer on the substrate. The cavity may extend in a wiring pattern, and a metal catalyst pattern may be included in the cavity. The carbon nanotube may be formed from the metal catalyst pattern, and may extend inside the cavity along the wiring pattern.

In some embodiments, a sacrificial layer pattern having the wiring pattern may be formed on the substrate, and the first layer may be formed on the substrate and the sacrificial layer pattern. At least a portion of the sacrificial layer pattern may be selectively removed after forming the first layer on the sacrificial layer pattern to define the cavity between the first layer and the substrate.

In other embodiments, a contact hole may be formed extending through the first layer to expose at least a portion of the sacrificial layer pattern.

In some embodiments, the sacrificial layer pattern may be a different material than the first layer and/or the substrate. An etching solution may be provided through the contact hole to selectively remove the sacrificial layer pattern. For example, the etching solution may be carbolic acid (CH₃OOH), hydrogen fluoride (HF) and/or hydrogen peroxide (H₂O₂).

In other embodiments, a sacrificial layer may be formed on the substrate, and the sacrificial layer may be patterned to define the sacrificial layer pattern. The sacrificial layer pattern may include a first portion extending in a first direction, and a second portion connected to the first portion and extending in a second direction. The first direction may be substantially perpendicular to the second direction. The contact hole may be formed extending through the sacrificial layer pattern at a connection point of the first and second portions.

In some embodiments, the metal catalyst pattern may be formed in the contact hole. For example, a spacer may be formed in the contact hole on sidewalls of the contact hole, and the metal catalyst pattern may be formed in the contact hole so that the spacer is between the metal catalyst pattern and the sidewalls of the contact hole.

In other embodiments, the contact hole may further extend through the sacrificial layer to expose a portion of a layer below the sacrificial layer. A recess may be formed in the portion of the layer below the sacrificial layer, and the metal catalyst pattern may be formed in the recess.

In some embodiments, the sacrificial layer pattern and the spacer may be selectively removed to define the cavity including the metal catalyst pattern in the cavity. For example, the spacer and the sacrificial layer pattern may be formed of substantially similar materials, and an etching solution may be provided through the contact hole to selectively remove the sacrificial layer pattern and the spacer and define the cavity connected to the contact hole.

In other embodiments, a metal catalyst layer may be formed on the first layer and in the contact hole. The metal catalyst layer may be recessed to expose the first layer and provide the metal catalyst pattern in the contact hole below a surface of the first layer. For example, the metal catalyst layer may be recessed using a chemical-mechanical polishing (CMP) process and/or an etching process.

In some embodiments, a second layer may be formed on the metal catalyst pattern to fill the contact hole. An opening may be formed extending through the first layer and the sacrificial layer, and an etching solution may be provided through the opening to selectively remove the sacrificial layer pattern and define the cavity. In addition, a carbon-containing source gas may be provided into the cavity through the opening to grow the carbon nanotube from the metal catalyst pattern in the cavity. A third layer on the first layer to cover the opening after forming the carbon nanotube.

In other embodiments, the sacrificial layer pattern may be a silicon compound. In addition, the first layer may be an insulating layer.

In some embodiments, in forming the carbon nanotube, a source gas may be provided to the metal catalyst pattern in the cavity. The carbon nanotube may be grown from a reaction between the source gas and the metal catalyst pattern so that the carbon nanotube extends inside the cavity along the wiring pattern.

In some embodiments, the cavity may include a contact hole extending through the first layer and connected to the cavity. A carbon-containing source gas may be provided into the cavity through the contact hole. The carbon-containing source gas may be thermally decomposed to provide carbon, and the carbon may be adsorbed to a sidewall of the metal catalyst pattern to grow the carbon nanotube from the metal catalyst pattern.

In other embodiments, the carbon nanotube may be formed at a temperature of about 400° C. to about 700° C. and/or at a pressure of about 10 Torr to about 300 Torr.

In some embodiments, an insulating, conductive, and/or semiconductor layer may be formed between the cavity and the substrate.

According to still further embodiments of the present invention, a method of forming a carbon nanotube may include forming a sacrificial layer pattern having a predetermined wiring pattern on a substrate. An insulating layer may be formed on the substrate and the sacrificial layer pattern, and a contact hole may be formed extending through the insulating layer and the sacrificial layer pattern. A spacer may be formed in the contact hole on opposing sidewalls of the contact hole, and a metal catalyst pattern may be formed in the contact hole such that the spacer is between the metal catalyst pattern and the sidewalls of the contact hole. The sacrificial layer pattern and the spacer may be selectively removed to define a cavity between the substrate and the insulating layer on the substrate, such that the cavity may extend in the predetermined wiring pattern. The carbon nanotube may be grown from the metal catalyst pattern to extend inside the cavity along the predetermined wiring pattern.

According to other embodiments of the present invention, an integrated circuit device may include a substrate, a first layer on the substrate, and a hollow cavity extending in a predetermined wiring pattern between the substrate and the first layer on the substrate. The device may also include a metal catalyst pattern inside a portion of the cavity. The metal catalyst pattern may be configured to grow a carbon nanotube therefrom.

Accordingly, a wiring pattern including a carbon nanotube may be formed in a cavity and/or a tunnel provided on a substrate by providing a source gas including carbon onto a catalytic metal layer pattern, and by growing the carbon nanotube from the catalytic metal layer pattern. Since the wiring including the carbon nanotube may be formed in a cavity that was formed using a sacrificial layer pattern, the wiring including the carbon nanotube may be formed in a desired and/or predetermined structure by controlling a structure of the sacrificial layer pattern. In addition, the wiring including the carbon nanotube may be formed on the substrate by reducing an amount of the source gas that may be required for forming the wiring. Furthermore, the wiring including the carbon nanotube may enclose the catalytic metal layer pattern, which may thereby provide a connection between the catalytic metal layer and the wiring including the carbon nanotube.

### BRIEF DESCRIPTION OF THE DRAWINGS

FIGS. 1 to 8 are plan views illustrating methods of forming wirings including carbon nanotubes in accordance with some embodiments of the present invention;

FIGS. 9 to 16 are cross-sectional views illustrating methods of forming wirings including carbon nanotubes taken along lines of I-I′ in FIGS. 1 to 8, respectively;

FIGS. 17 to 21 are plan views illustrating methods of forming wirings including carbon nanotubes in accordance with further embodiments of the present invention; and

FIGS. 22 to 26 are cross-sectional views illustrating methods of forming wirings including carbon nanotubes taken along lines of II-II′ in FIGS. 17 to 21, respectively.

### DETAILED DESCRIPTION OF EMBODIMENTS OF THE INVENTION

The present invention is described more fully hereinafter with reference to the accompanying drawings, in which embodiments of the present invention are shown. The present invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity. Like reference numerals refer to like elements throughout.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer and/or section. Thus, a first element, component, region, layer and/or section discussed below could be termed a second element, component, region, layer and/or section without departing from the teachings of the present invention.

Spatially relative terms, such as “beneath”, “below”, “lower”, “under”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would be oriented “above” the other elements or features. Thus, the exemplary terms “below” and “under” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the present invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

Embodiments of the present invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and/or the present specification and will not be interpreted in an idealized or overly formal sense unless expressly so defined herein.

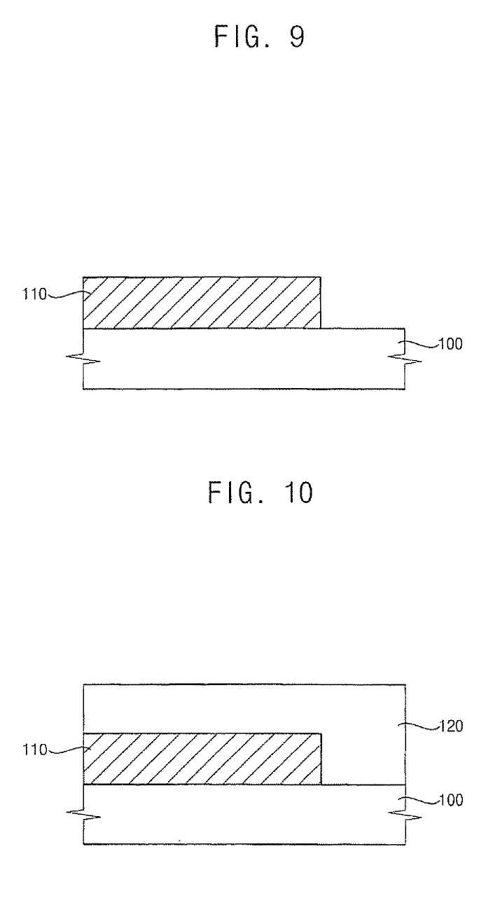

FIGS. 1 to 8 are plan views illustrating methods of forming wirings including carbon nanotubes in accordance with some embodiments of the present invention. FIGS. 9 to 16 are cross-sectional views illustrating methods of forming wirings including carbon nanotubes taken along lines of I-I′ in FIGS. 1 to 8, respectively.

FIGS. 1 and 9 illustrate the formation of a sacrificial layer pattern on a substrate 100. Referring now to FIGS. 1 and 9, a sacrificial layer pattern 110 is formed on the substrate 100. The substrate 100 may include a semiconductor substrate such as a silicon wafer and/or a silicon-on-insulator (SOI) substrate. In addition, the substrate 100 may include a metal substrate and/or a metal oxide substrate.

In some embodiments of the present invention, a lower structure may be formed between the substrate 100 and the sacrificial layer pattern 110. The lower structure may include a conductive layer pattern, a contact region, an insulation layer pattern, a pad, a plug, a gate structure and/or a transistor. For example, the lower structure may include a first contact region and a second contact region where a capacitor and a bit line may be electrically connected when an integrated circuit memory device is formed on the substrate 100.

In other embodiments of the present invention, an insulation structure may be formed on the substrate 100 to cover the lower structure before forming the sacrificial layer pattern 110. The insulation structure may include one or more insulating interlayers. For example, the insulating interlayer may be formed using an oxide, such as boro-phosphor silicate glass (BPSG), phosphor silicate glass (PSG), undoped silicate glass (USG), spin on glass (SOG), flowable oxide (FOX), tetraethylorthosilicate (TEOS), plasma enhanced-tetraethylorthosilicate (PE-TEOS) and/or high density plasma-chemical vapor deposition (HDP-CVD) oxide. The insulation structure may further include an additional oxide layer and/or an additional nitride layer.

In the formation of the sacrificial layer pattern 110, a sacrificial layer may be formed on the substrate 100, and a photoresist pattern may be formed on the sacrificial layer. The sacrificial layer may be formed using a material that has an etching selectivity relative to the insulating structure and the substrate 100. For example, the sacrificial layer may be formed using a silicon compound, such as silicon-germanium (Si—Ge). In some embodiments of the present invention, the photoresist pattern may have a shape that is substantially similar to that of a desired and/or predetermined wiring pattern 170 (see FIG. 16). The sacrificial layer may be partially etched using the photoresist pattern as an etching mask to form the sacrificial layer pattern 110 on the substrate 100. The sacrificial layer pattern 110 may be formed using a wet etching process and/or a dry etching process. In addition, the sacrificial layer pattern 110 may be formed on the substrate 100 using a damascene process.

In some embodiments of the present invention, the sacrificial layer pattern 110 includes a first portion 112 and a second portion 114 as shown in FIG. 1. The first portion 112 of the sacrificial layer pattern 110 may extend along a first direction on the substrate 100, whereas the second portion 114 of the sacrificial layer pattern 110 may extend along a second direction on the substrate 100. In some embodiments, the first direction may be substantially perpendicular to the second direction. That is, the first portion 112 may be substantially perpendicular to the second portion 114. In addition, the sacrificial layer pattern 110 may include one first portion 112 extending along the first direction and two second portions 114 extending along the second direction. The first portion 112 may be interposed between the two second portions 114. Thus, the first portion 112 may connect one second portion 114 to the other second portion 114.

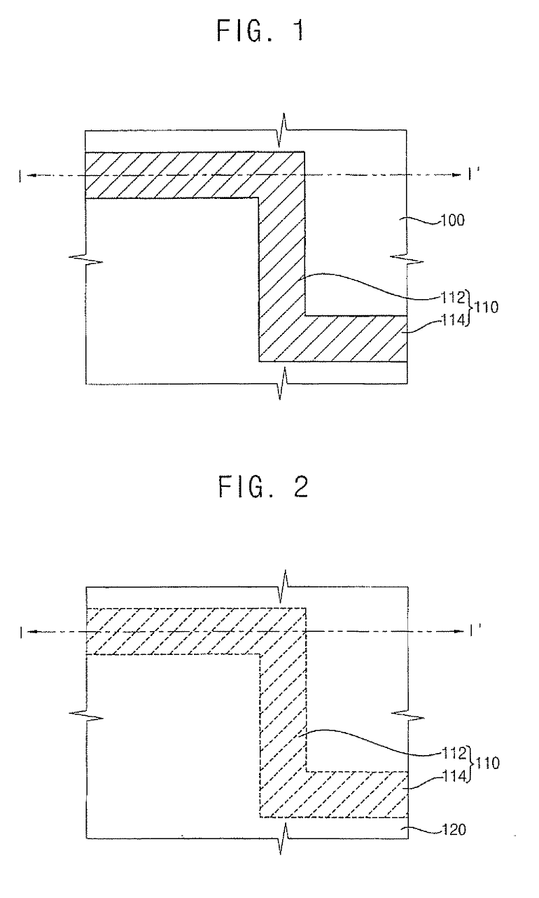

FIGS. 2 and 10 illustrate the formation of an insulation layer on the sacrificial layer pattern 110. Referring to FIGS. 2 and 10, an insulation layer 120 is formed on the substrate 100 and on the sacrificial layer pattern 110. The insulation layer 120 may be formed using an oxide. For example, the insulation layer 120 may be formed using BPSG, PSG, SOG, USG, FOX, TEOS, PE-TEOS and/or HDP-CVD oxide. Additionally, the insulation layer 120 may be formed using, for example, a CVD process, a PE-CVD process, an HDP-CVD process, and/or a spin coating process.

In some embodiments of the present invention, the insulation layer 120 may be planarized using a chemical mechanical polishing (CMP) process, an etch-back process or a combination of CMP and/or etch-back processes.

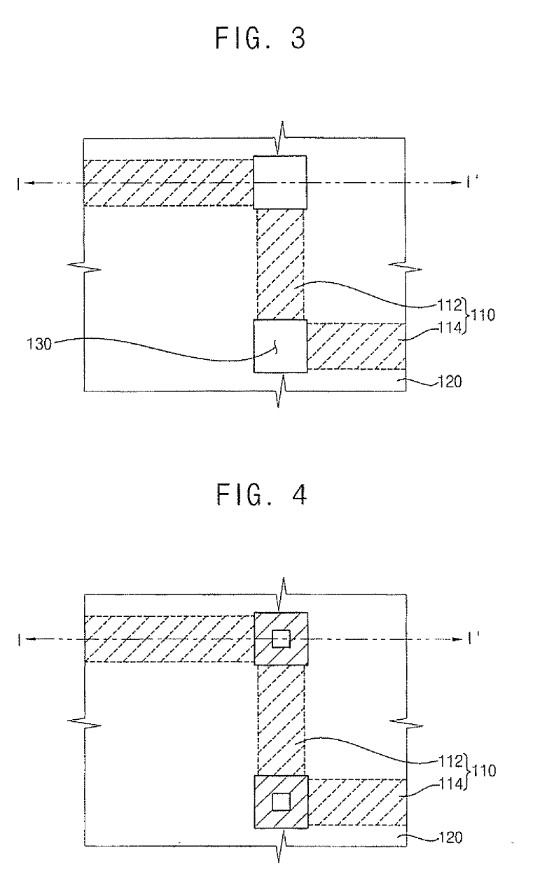

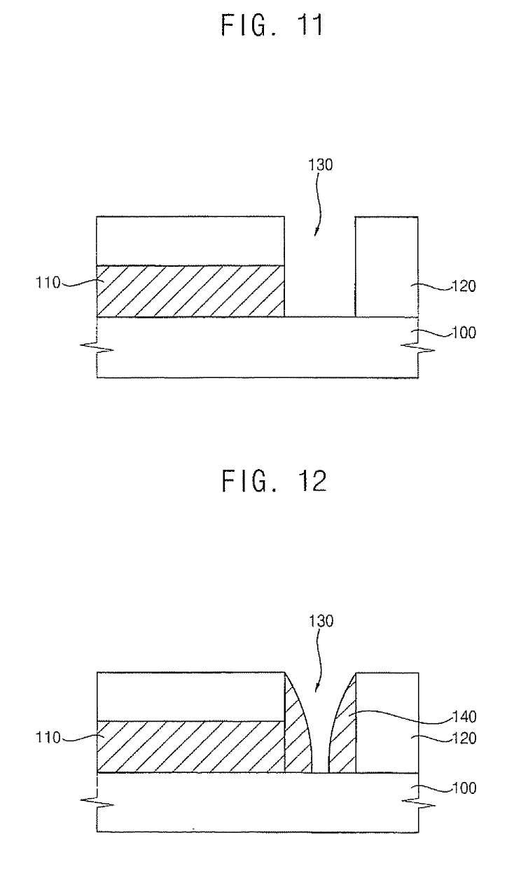

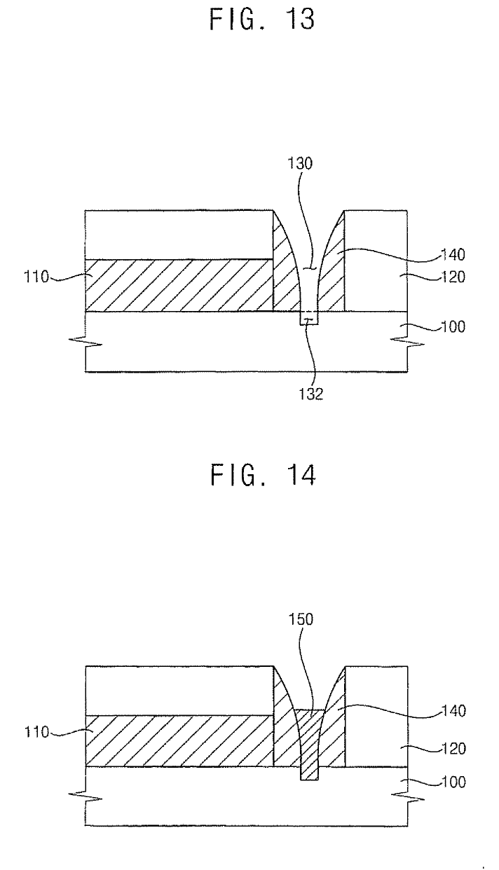

FIGS. 3 and 11 illustrate the formation of a contact hole through the insulation layer 120 and the sacrificial layer pattern 110. Referring to FIGS. 3 and 11, the insulation layer 120 and the sacrificial layer pattern 110 are partially etched to form a contact hole 130 that exposes at least a portion of the substrate 100. More particularly, a mask (not shown) is formed on the insulation layer 120 to expose a portion of the insulation layer 120 where the first portion 112 of the sacrificial layer pattern 110 is connected to the second portion 114 of the sacrificial layer pattern 110. Using the mask as an etching mask, the insulation layer 120 and the sacrificial layer pattern 110 are successively etched to form the contact hole 130. The contact hole 130 may expose a sidewall of the sacrificial layer pattern 110. After the mask is removed from the insulation layer 120, the contact hole 130 extending through the insulation layer 120 and the sacrificial layer pattern 110 and exposing the portion of the substrate 100 and the sidewall of the sacrificial layer pattern 110 is completed.

FIGS. 4 and 12 illustrate the formation of a spacer on a sidewall of the contact hole 130. Referring to FIGS. 4 and 12, a spacer 140 is formed on the sidewall of the contact hole 130 including a sidewall of the insulation layer 120 and the exposed sidewall of the sacrificial layer pattern 110. Thus, the spacer 140 is positioned on the sidewalls of the sacrificial layer pattern 110 and the insulation layer 120.

In the formation of the spacer 140, a layer may be uniformly formed on the insulation layer 120, the sidewall of the contact hole 130 and the exposed portion of the substrate 100. The layer may be formed using a material substantially the same as that of the sacrificial layer pattern 110. The layer may be anisotropically etched until the substrate 100 is exposed to form the spacer 140 on the sidewall of the contact hole 130. For example, the spacer 140 may be formed by a plasma etching process. In addition, the spacer 140 may be formed by an etch-back process.

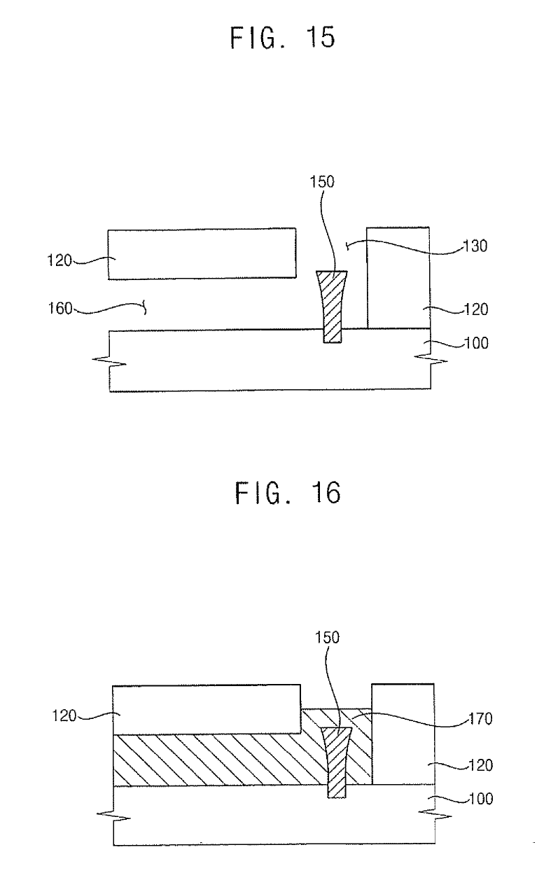

The spacer 140 may be used to form a metal catalyst pattern 150 (see FIG. 6) in the contact hole 130. Additionally, the spacer 140 may be removed along with the sacrificial layer pattern 110 to define a cavity or tunnel 160 (see FIG. 15), which may be used to form wiring 170 on the substrate 100 in a subsequent process. More particularly, a source material, such as a carbon-containing gas, may be introduced into the cavity or the tunnel 160 to form a wiring 170 including a carbon nanotube on the substrate 100, as will be further described below.

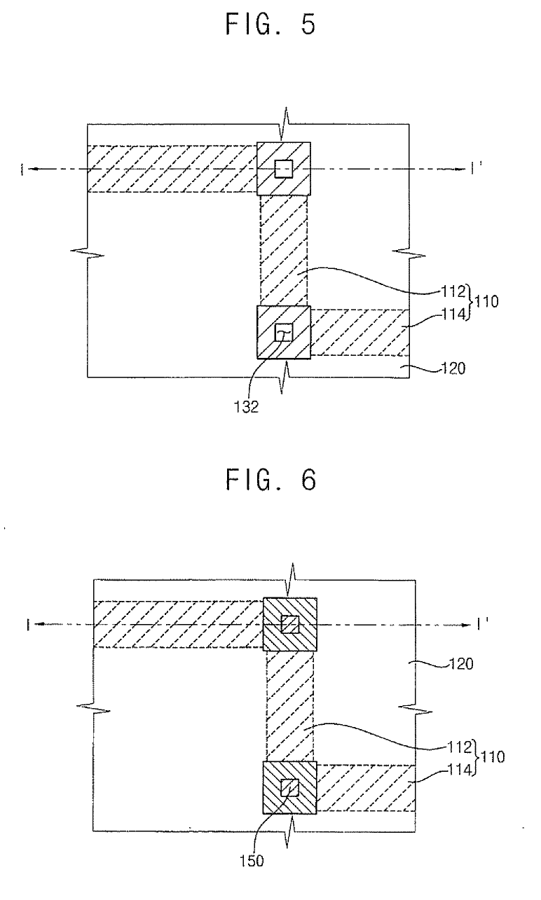

FIGS. 5 and 13 illustrate the formation of a recess on the substrate 100. Referring to FIGS. 5 and 13, the exposed portion of the substrate 100 is selectively etched to form a recess 132 on the substrate 100. The recess 132 may be formed by a wet etching process and/or a dry etching process. For example, a protective mask may be formed on the insulation layer 120 to reduce and/or prevent the insulation layer 120 from being damaged in the etching process used to form the recess 132. The protective mask may be formed of a nitride and/or an oxynitride layer.

A lower portion of the metal catalyst pattern 150 (see FIG. 14) may be formed in the recess 132. Thus, the recess 132 may support the metal catalyst pattern 150 in the contact hole 130 after the spacer 140 and the sacrificial layer pattern 110 are removed. That is, the metal catalyst pattern 150 may not “fall down” in the contact hole 130 due to the support provided by the recess 132.

FIGS. 6 and 14 illustrate a step of forming the metal catalyst pattern 150 in the contact hole 132. Referring to FIGS. 6 and 14, a metal layer is formed on the insulation layer 120 to fill the contact hole 130 in which the spacer 140 is positioned. The metal layer may be formed using a metal that serves as a catalyst for forming the carbon nanotube. For example, the metal layer may be nickel (Ni), cobalt (Co), iron (Fe) and/or a combination thereof.

The metal layer is partially removed to form the metal catalyst pattern 150 in the contact hole 130. The metal catalyst pattern 150 may make contact with the substrate 100. The metal catalyst pattern 150 may also have an upper surface that is substantially lower than that of the insulation layer 120. Since the recess 132 is formed in the contact hole 130, the recess 132 is filled with the lower portion of the metal catalyst pattern 150.

In some embodiments of the present invention, a CMP process may be used to recess the metal layer until the insulation layer 120 is exposed to form a preliminary metal catalyst pattern in the contact hole 130. The preliminary metal catalyst pattern may be partially etched to form the metal catalyst pattern 150 that has the upper surface substantially lower than that of the insulation layer 120. The preliminary metal catalyst pattern may be partially etched using an anisotropic etching process. The upper face of the metal catalyst pattern 150 may also be substantially the same height as that of the sacrificial layer pattern 110.

In some embodiments of the present invention, a first etching process may be used to recess the metal layer until the insulation layer 120 is exposed to thereby form a preliminary metal catalyst pattern in the contact hole 130. The first etching process may include a first dry etching process. The preliminary metal catalyst pattern may be partially etched using a second etching process to form the metal catalyst pattern 150 that has the upper face substantially lower than that of the insulation layer 120 and also substantially the same as that of the sacrificial layer pattern 110. The second etching process may include a second dry etching process. The first and the second etching processes may be carried out in-situ.

In some embodiments of the present invention, a cleaning process may be performed on the substrate 100 to remove etched residues existing on the insulation layer 120 and the metal catalyst pattern 150 after the formation of the metal catalyst pattern 150. The cleaning process may be carried out using an isopropyl alcohol (IPA) solution and/or deionized water.

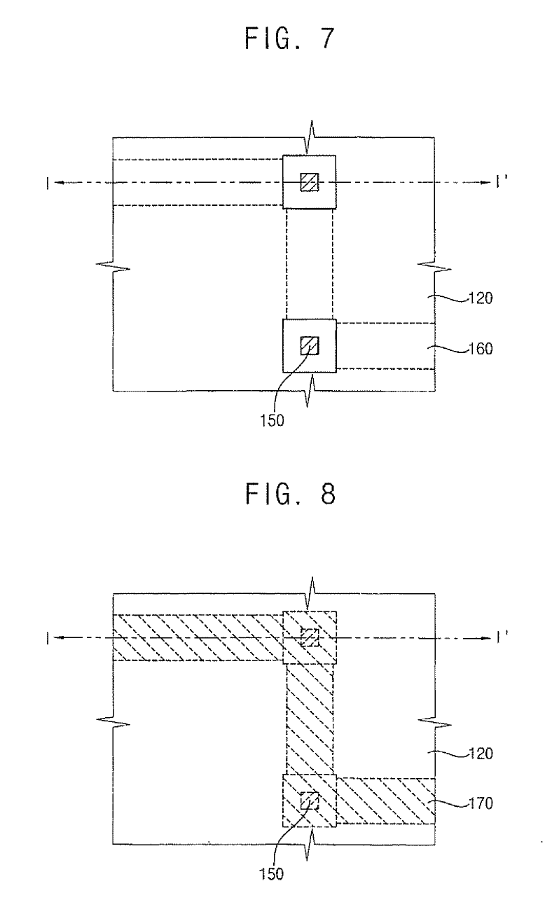

FIGS. 7 and 15 illustrate the removal of the sacrificial layer pattern 110 and the spacer 140. Referring to FIGS. 7 and 15, the spacer 140 and the sacrificial layer pattern 110 are selectively removed from the substrate 100 to define the cavity or a tunnel 160 connected to the contact hole 130. That is, the sacrificial layer pattern 110 and the spacer 140 are selectively removed to form the cavity 160 (which will be used to form the wiring 170) between the substrate 100 and the insulation layer 120. The spacer 140 and the sacrificial layer pattern 110 may be selectively removed using an etching solution that has a higher etching rate with respect to the spacer 140 and the sacrificial layer pattern 110 than with respect to the insulation layer 120 and the substrate 100. In other words, the etching solution may be selected so as to etch the spacer 140 and the sacrificial layer pattern 110 at a faster rate than the insulation layer 120 and the substrate 100. The etching solution may be provided through the contact hole 130 to etch the spacer 140 and the sacrificial layer pattern 110. When the cavity or the tunnel 160 is formed on the substrate 100 by selectively removing the spacer 140 and the sacrificial layer pattern 110, the metal catalyst pattern 150 may be supported because the lower portion of the catalytic layer pattern 150 is buried in the recess 132. Additionally, the contact hole 130 may have an increased width when the spacer 140 is removed, such that the contact hole 130 may be connected to the cavity 160.

In some embodiments of the present invention, the etching solution used to form the cavity 160 may include a carboxylic acid (CH₃COOH) solution, a hydrogen fluoride (HF) solution, and/or a hydrogen peroxide (H₂O₂) solution, for example, when the spacer 140 and the sacrificial layer pattern 110 include silicon germanium.

FIGS. 8 and 16 illustrate the formation of wiring including a carbon nanotube on the substrate 100. Referring to FIGS. 8 and 16, a source material selected to form the carbon nanotube is introduced into the cavity 160 through the contact hole 130. Thus, conductive wiring 170 including the carbon nanotube is formed on the substrate 100 and in the cavity 160. Since the metal catalyst pattern 150 is located in the contact hole 130, the wiring 170 is also formed on the metal catalyst pattern 150.

In some embodiments of the present invention, the wiring 170 including the carbon nanotube may be formed, for example, by a CVD process, a low pressure CVD (LPCVD) process, a sub-atmospheric CVD (SACVD) process and/or a PECVD process. The source material may include a carbon containing gas. Examples of the carbon containing gas may include a methane gas, an acetylene gas, and/or a carbon monoxide gas. The wiring 170 including the carbon nanotube may be formed at a temperature of about 400° C. to about 700° C., and at a pressure of about 10 Torr to about 300 Torr.

When the wiring 170 including the carbon nanotube is formed by a CVD process using a carbon containing gas, the carbon containing gas may be thermally decomposed, and may be provided onto the metal catalyst pattern 150 through the contact hole 130. The carbon containing gas may be adsorbed to the metal catalyst pattern 150, and the carbon nanotube may be continuously grown from the metal catalyst pattern 150 along the cavity 1601 thereby forming the wiring 170 including the carbon nanotube in the cavity 160 and the contact hole 130.

In some embodiments of the present invention, the wiring 170 may have an upper surface that extends substantially lower than that of the insulation layer 120. Additionally, the upper surface of the wiring 170 may extend slightly higher than that of the metal catalyst pattern 150.

Since the wiring 170 including the carbon nanotube may be grown from the metal catalyst pattern 150, the wiring 170 including the carbon nanotube may be partially removed when the wiring 170 may grow out of the contact hole 130 and onto the insulation layer 120. For example, the wiring 170 may be partially removed by a CMP process and/or an etch-back process.

According to some embodiments of the present invention, the wiring 170 including the carbon nanotube may be formed to have a desired structure and/or predetermined pattern by controlling the structure of the sacrificial layer pattern 110. In other words, the cavity 160 may be formed by forming the sacrificial layer pattern 110 in a desired wiring pattern, and the wiring 170 including the carbon nanotube may be grown inside the cavity 160 along the desired wiring pattern. Additionally, the wiring 170 including the carbon nanotube may be more economically formed on the substrate 100 because the wiring 170 including the carbon nanotube may be grown from the metal catalyst pattern 150 inside the cavity or tunnel 160 using a reduced amount of the source gas.

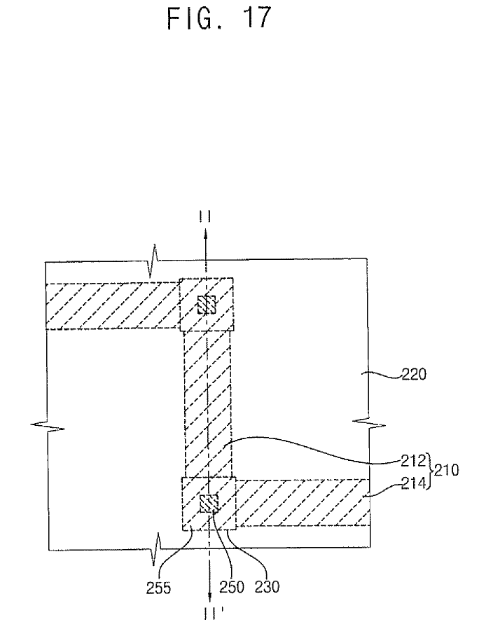

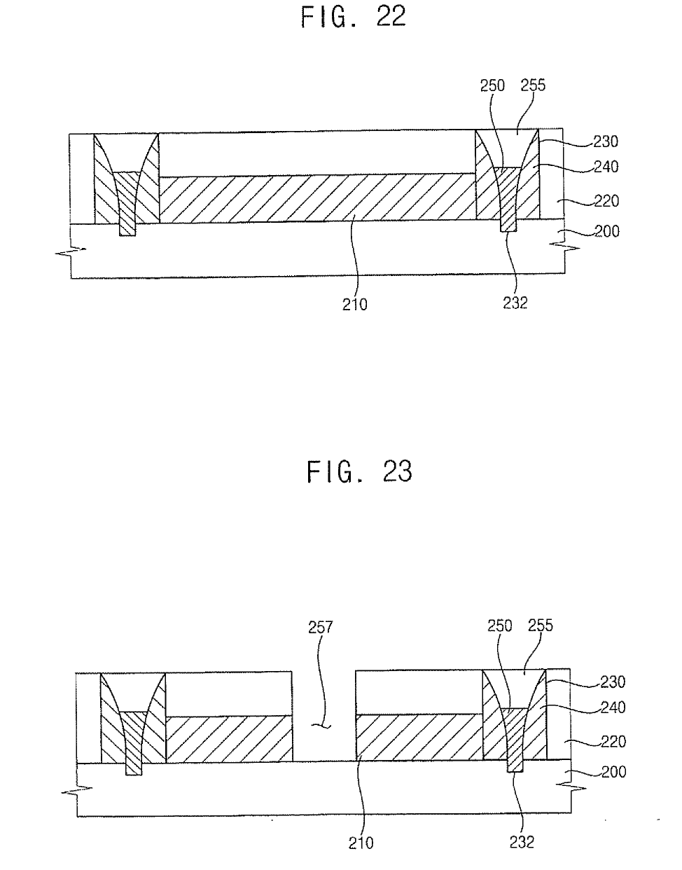

FIGS. 17 to 21 are plan views illustrating methods of forming wirings including carbon nanotubes in accordance with further embodiments of the present invention, FIGS. 22 to 26 are cross-sectional views illustrating methods of forming wirings including carbon nanotubes taken along lines of II-II′ in FIGS. 17 to 21, respectively.

FIGS. 17 and 22 illustrate the formation of a sacrificial layer pattern 210, a first insulation layer 220, a contact hole 230, a spacer 240, a metal catalyst pattern 250 and an insulation layer pattern 255 on a substrate 200. Referring to FIGS. 17 and 22, after the sacrificial layer pattern 210 is formed on the substrate 200, the first insulation layer 220 is formed on the substrate 200 and on the sacrificial layer pattern 210. The sacrificial layer pattern 210 includes a first portion 212 and a second portion 214. The first portion 212 of the sacrificial layer pattern 210 is formed extending along a first direction on the substrate 200, whereas the second portion 214 of the sacrificial layer pattern 210 is formed extending along a second direction that is substantially perpendicular to the first direction.

A contact hole 230 is formed extending through the first insulation layer 220 and the sacrificial layer pattern 210 to expose a first portion of the substrate 200. The contact hole 230 is formed by partially etching the first insulation layer 220 and the sacrificial layer pattern 230.

A spacer 240 is formed on a sidewall of the contact hole 230. The spacer 240 may be formed from a material selected to be etched at a substantially similar rate as the sacrificial layer pattern 210. For example, the spacer 240 and the sacrificial layer pattern 210 may both be formed of silicon compounds, such as silicon-germanium.

After a recess 232 is formed in the exposed first portion of the substrate 200, the metal catalyst pattern 250 is formed on the substrate 200 to at least partially fill the contact hole 230. A lower portion of the catalytic metal layer 250 is buried in the recess 232. More particularly, a metal layer may be formed on the first insulation layer 220 to fill the recess 232 and the contact hole 230. The metal layer may be formed using a metal that serves as a catalyst for forming wiring 270 (see FIG. 25), that includes a carbon nanotube. The metal layer may be partially removed so that the metal catalyst pattern 250 has an upper surface that is substantially lower than the first insulation layer 220. Additionally, the upper surface of the metal catalyst pattern 250 may be substantially similar in height as that of the sacrificial layer pattern 210.

In some embodiments of the present invention, etched residues remaining on the metal catalyst pattern 250 and/or the first insulation layer 220 may be removed by a cleaning process after the metal catalyst pattern 250 is formed in the contact hole 230 and in the recess 232.

Still referring to FIGS. 17 and 22, a second insulation layer is formed on the metal catalyst pattern 250 and the first insulation layer 220 to fill the contact hole 230. The second insulation layer is partially removed from the first insulation layer 220 to thereby form the second insulation layer pattern 255 in the contact hole 230 on the metal catalyst pattern 250. The second insulation layer pattern 255 may partially and/or completely fill the contact hole 230. The second insulation layer pattern 255 may be formed by a CMP process, an etch-back process, and/or a combination of CMP and/or etch-back processes.

In some embodiments of the present invention, the second insulation layer pattern 255 may fill the contact hole 230. In further embodiments of the present invention, the second insulation layer pattern 255 may be formed on the first insulation layer 220 while filling the contact hole 230.

The second insulation layer pattern 255 may reduce the likelihood of growth of the wiring 270 including the carbon nanotube from the upper surface of the metal catalyst pattern 250. Therefore, the wiring 270 including the carbon nanotube may be formed without any additional processes, such as a CMP process and/or an etch-back process. In addition, an amount of a source gas which may be used to form the wiring 270 may be reduced, because the source gas may not be provided onto the upper surface of the metal catalyst pattern 250.

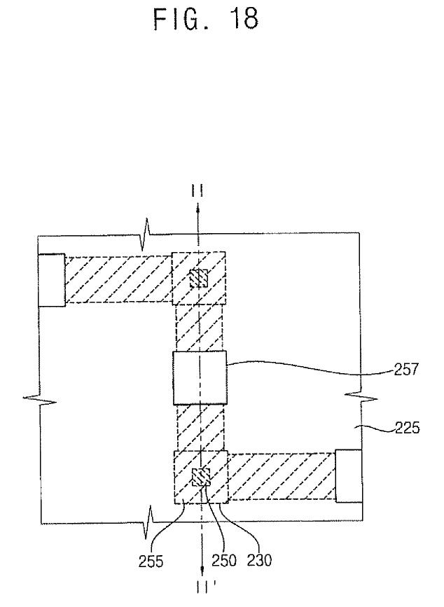

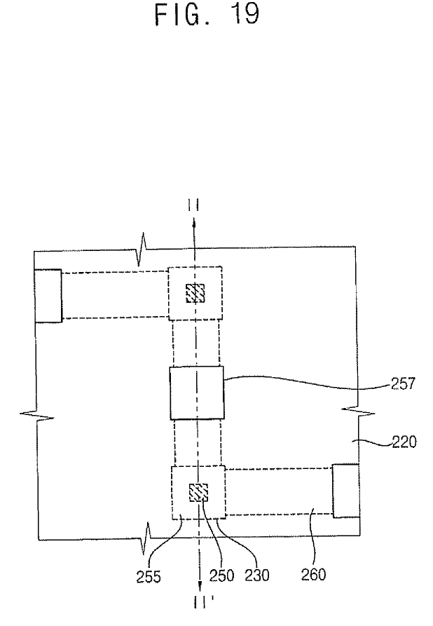

FIGS. 18 and 23 illustrate the formation of an opening 257 through the first insulation layer 220 and the sacrificial layer pattern 210. Referring to FIGS. 18 and 23, the opening 257 is formed through the first insulation layer 250 and the sacrificial layer pattern 210 to expose a second portion of the substrate 200. In subsequent processes, an etching solution used to remove the sacrificial layer pattern 210 and/or the spacer 240 may be provided through the opening 257. Also the source gas may be provided through the opening 257 to grow the carbon nanotube.

During the formation of the opening 257, a protective mask may be formed on the first insulation layer 220 to expose a portion of the first insulation layer 220 away from the metal catalyst pattern 250. The exposed portion of the first insulation layer 220 and the sacrificial layer pattern 210 may be etched using the protection mask as an etching mask, thereby forming the opening 257 exposing the second portion of the substrate 200. Additionally, sidewalls of the first insulation layer 220 and the sacrificial layer 210 may be exposed through the opening 257. The protective mask may be removed from the insulation layer 220.

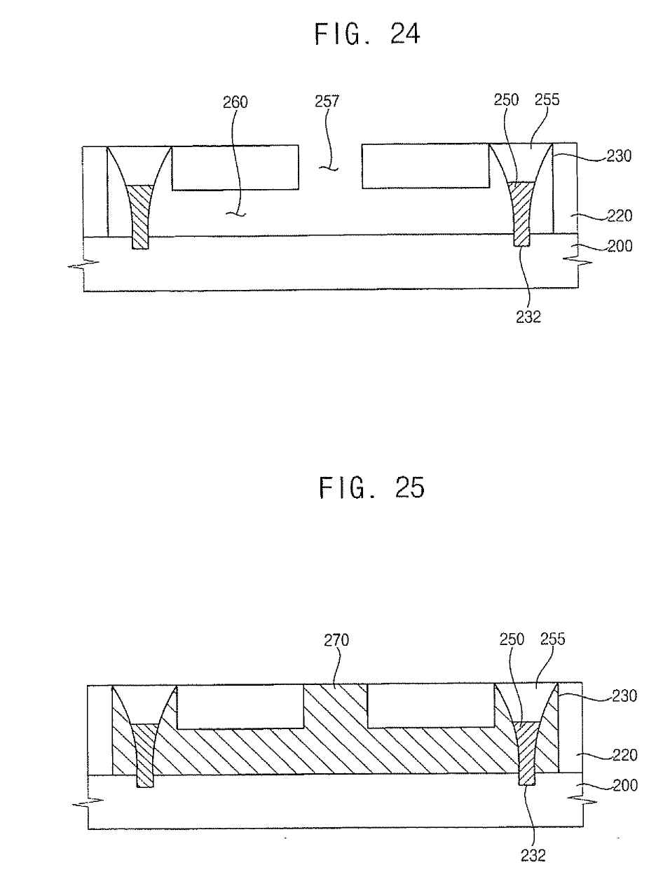

FIGS. 19 and 24 illustrate removal of the spacer 240 and the sacrificial layer pattern 210. Referring to FIGS. 19 and 24, the sacrificial layer pattern 210 and the spacer 240 are removed from the substrate 200 using a wet etching process. The sacrificial layer pattern 210 and the spacer 240 may be simultaneously removed and/or separately removed. Accordingly, a cavity or a tunnel 260 is formed between the substrate 200 and the first insulation layer 220. The cavity 260 may be formed using an etching solution that has a higher etch rate with respect to the spacer 240 and the sacrificial layer pattern 210 than with respect to the substrate 200, the metal catalyst pattern 250, the first insulation layer 220, and/or the second insulation layer pattern 255. The etching solution is provided to the sacrificial layer pattern 210 and the spacer 240 through the opening 257. Thus, the cavity or the tunnel 260 is connected to the contact hole 230 by selectively removing the spacer 240 and the sacrificial layer pattern 210.

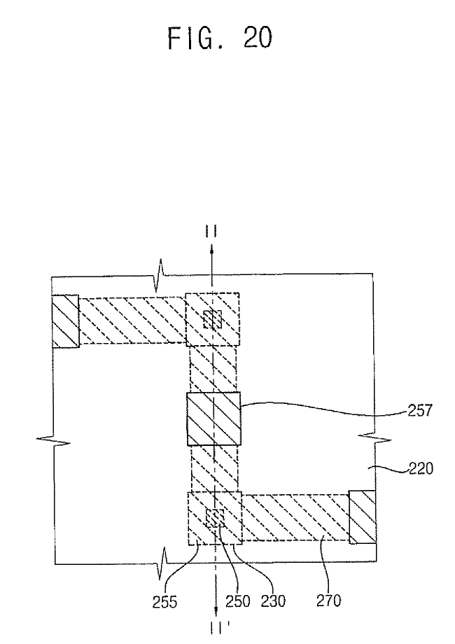

FIGS. 20 and 25 illustrate the formation of the wiring 270 including the carbon nanotube. Referring to FIGS. 20 and 25, a source gas including carbon (for forming the carbon nanotube) is provided through the opening 257 to a sidewall of the metal catalyst pattern 250 inside the cavity 260. As such, the wiring 270 including the carbon nanotube is grown from the metal catalyst pattern 250 to fill the cavity 260 and the contact hole 230. Therefore, the wiring 270 including the carbon nanotube encloses the metal catalyst pattern 250.

In some embodiments of the present invention, the source gas including carbon may be thermally decomposed, and may be adsorbed to the sidewall of the metal catalyst pattern 250 through the opening 257 and the cavity 260. Thus, the carbon nanotube may be grown from the sidewall of the metal catalyst pattern 250 to fill the contact hole 230 and the cavity 260. As a result, the wiring 270 including the carbon nanotube encloses the metal catalyst pattern 250, and extends along the desired wiring pattern.

In further embodiments of the present invention, the wiring 270 including the carbon nanotube may be partially removed by a CMP process and/or an etch-back process when the carbon nanotube is grown to extend out of the opening 257.

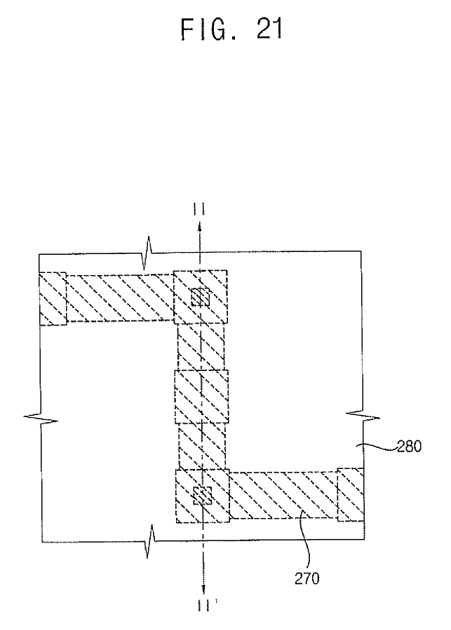

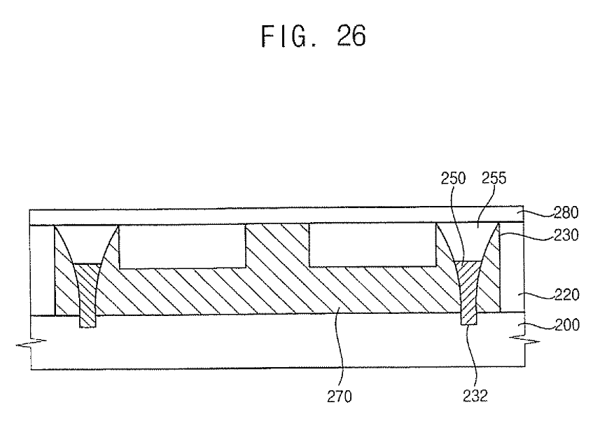

FIGS. 21 and 26 illustrate the formation of a third insulation layer 280 on the first insulation layer 220, the second insulation layer pattern 255, and the wiring 270. Referring to FIGS. 21 and 26, the third insulation layer 280 is formed on the first insulation layer 220 and the second insulation layer pattern 255 to cover the wiring 270 including the carbon nanotube. The third insulation layer 280 may be formed using an oxide, such as BPSG, PSG, SOG, USG, FOX, TEOS, PE-TEOS and/or HDP-CVD oxide. The third insulation layer 280 may electrically insulate the wiring 270 including the carbon nanotube from a subsequently formed upper wiring.

In some embodiments of the present invention, the third insulation layer 280 may be planarized by a CMP process, an etch-back process or a combination of CMP and/or etch-back processes.

Thus, according to some embodiments of the present invention, wiring including a carbon nanotube may be formed in a cavity or a tunnel provided on a substrate by supplying a source gas including carbon to a metal catalyst pattern in the cavity, and growing the carbon nanotube from the metal catalyst pattern. Since the cavity or tunnel may be formed using a sacrificial layer pattern, the wiring including the carbon nanotube may be formed to have a desired and/or predetermined structure or wiring pattern by adjusting a structure of the sacrificial layer pattern. Additionally, the wiring including the carbon nanotube may be more economically formed on the substrate by reducing an amount of the source gas that may be required to form the wiring. Furthermore, the wiring including the carbon nanotube may enclose the metal catalyst pattern, which may provide a connection between the metal catalyst pattern and the wiring including the carbon nanotube.

While the present invention has been particularly shown and described with reference to exemplary embodiments thereof it will be understood by those of ordinary skill in the art that various changes in form and details may be made therein without departing from the spirit and scope of the present invention as defined by the following claims and their equivalents.

That which is claimed:

1. A method of forming a carbon nanotube, the method comprising:
forming a cavity between a substrate and a first layer on the substrate, the cavity extending in a wiring pattern and including a metal catalyst pattern in the cavity; and
forming the carbon nanotube from the metal catalyst pattern and extending inside the cavity along the wiring pattern.

2. The method of claim 1, wherein forming the cavity comprises:
forming a sacrificial layer pattern having the wiring pattern on the substrate;
forming the first layer on the substrate and the sacrificial layer pattern; and
selectively removing at least a portion of the sacrificial layer pattern after forming the first layer on the sacrificial layer pattern to define the cavity between the first layer and the substrate.

3. The method of claim 2, wherein forming the cavity further comprises:
forming a contact hole extending through the first layer to expose at least a portion of the sacrificial layer pattern.

4. The method of claim 3, wherein the sacrificial layer pattern comprises a different material than the first layer and/or the substrate, and wherein selectively removing the sacrificial layer pattern comprises:
providing an etching solution through the contact hole to selectively remove the sacrificial layer pattern.

5. The method of claim 4, wherein the etching solution comprises carbolic acid (CH₃OOH), hydrogen fluoride (HF) and/or hydrogen peroxide (H₂O₂).

6. The method of claim 3, wherein forming the sacrificial layer pattern comprises:
forming a sacrificial layer on the substrate; and
patterning the sacrificial layer to define the sacrificial layer pattern including a first portion extending in a first direction, and a second portion connected to the first portion and extending in a second direction.

7. The method of claim 6, wherein the first direction is substantially perpendicular to the second direction, and wherein forming the contact hole comprises:
forming the contact hole extending through the sacrificial layer pattern at a connection point of the first and the second portions.

8. The method of claim 3, wherein forming the cavity further comprises:
forming the metal catalyst pattern in the contact hole.

9. The method of claim 8, further comprising:
forming a spacer on sidewalls of the contact hole; and
forming the metal catalyst pattern in the contact hole so that the spacer is between the metal catalyst pattern and the sidewalls of the contact hole.

10. The method of claim 9, wherein the contact hole further extends through the sacrificial layer to expose a portion of a layer below the sacrificial layer, and further comprising:
forming a recess in the portion of the layer below the sacrificial layer; and
forming the metal catalyst pattern in the recess.

11. The method of claim 9, wherein selectively removing the sacrificial layer pattern comprises:
selectively removing the sacrificial layer pattern and the spacer to define the cavity including the metal catalyst pattern in the cavity.

12. The method of claim 11, wherein the spacer and the sacrificial layer pattern comprise substantially similar materials, and wherein selectively removing the sacrificial layer pattern and the spacer comprises:
providing an etching solution through the contact hole to selectively remove the sacrificial layer pattern and the spacer and to define the cavity connected to the contact hole.

13. The method of claim 8, wherein forming the metal catalyst pattern comprises:
forming a metal catalyst layer on the first layer and in the contact hole; and
recessing the metal catalyst layer to expose the first layer and to provide the metal catalyst pattern in the contact hole below a surface of the first layer.

14. The method of claim 13, wherein recessing the metal catalyst layer comprises:
recessing the metal catalyst layer using a chemical-mechanical polishing (CMP) process and/or an etching process.

15. The method of claim 8, further comprising:
forming a second layer on the metal catalyst pattern to fill the contact hole; and
forming an opening extending through the first layer and the sacrificial layer,
wherein selectively removing the sacrificial layer pattern comprises providing an etching solution through the opening to define the cavity.

16. The method of claim 15, wherein forming the carbon nanotube comprises:
providing a carbon-containing source gas into the cavity through the opening to grow the carbon nanotube from the metal catalyst pattern in the cavity.

17. The method of claim 16, further comprising:
forming a third layer on the first layer to cover the opening after forming the carbon nanotube.

18. The method of claim 2, wherein the sacrificial layer pattern comprises a silicon compound.

19. The method of claim 1, wherein forming the carbon nanotube comprises:
providing a source gas to the metal catalyst pattern in the cavity; and
growing the carbon nanotube from a reaction between the source gas and the metal catalyst pattern so that the carbon nanotube extends inside the cavity along the wiring pattern.

20. The method of claim 19, wherein the cavity includes a contact hole extending through the first layer and connected to the cavity, and wherein providing the source gas comprises;
providing a carbon-containing source gas into the cavity through the contact hole.

21. The method of claim 20, wherein growing the carbon nanotube comprises:
thermally decomposing the carbon-containing source gas to provide carbon; and
adsorbing the carbon to a sidewall of the metal catalyst pattern to grow the carbon nanotube from the metal catalyst pattern.

22. The method of claim 1, wherein forming the carbon nanotube comprises:
forming the carbon nanotube at a temperature of about 400° C. to about 700° C. and/or at a pressure of about 10 Torr to about 300 Torr.

23. The method of claim 1, further comprising:
forming an insulating, conductive and/or semiconductor layer between the cavity and the substrate.

24. The method of claim 1, wherein the first layer comprises an insulating layer.

25. A method of forming a carbon nanotube, the method comprising:
forming a sacrificial layer pattern having a predetermined wiring pattern on a substrate;
forming an insulating layer on the substrate and the sacrificial layer pattern;
forming a contact hole extending through the insulating layer and the sacrificial layer pattern;
forming a spacer in the contact hole on opposing sidewalls of the contact hole;
forming a metal catalyst pattern in the contact hole such that the spacer is between the metal catalyst pattern and the sidewalls of the contact hole;
selectively removing the sacrificial layer pattern and the spacer to define a cavity between the substrate and the insulating layer on the substrate, wherein the cavity extends in the predetermined wiring pattern; and
growing the carbon nanotube from the metal catalyst pattern to extend inside the cavity along the predetermined wiring pattern.

26. An integrated circuit device, comprising:
a substrate;
a first layer on the substrate;
a hollow cavity extending in a predetermined wiring pattern between the substrate and the first layer on the substrate; and
a metal catalyst pattern inside a portion of the cavity, wherein the metal catalyst pattern is configured to grow a carbon nanotube therefrom.
